(19) United States
(12) Patent Application Publication
(10) Pub. No.: US 2013/0269751 A1
(43) Pub. Date: Oct. 17, 2013

(54) ADAPTIVE LENSES FOR SOLAR ENERGY COLLECTION

(71) Applicant: Afshin Izadian, Inidianapolis, IN (US)

(72) Inventor: Afshin Izadian, Inidianapolis, IN (US)

(21) Appl. No.: 13/838,867

(22) Filed: Mar. 15, 2013

Related U.S. Application Data
(63) Continuation-in-part of application No. 13/312,308, filed on Dec. 6, 2011.
(60) Provisional application No. 61/420,535, filed on Dec. 7, 2010.

(30) Foreign Application Priority Data
Dec. 6, 2011 (US) PCT/US11/63477

(51) Int. Cl. H01L 31/052; H01L 31/0232

(52) U.S. Cl. CPC H01L 31/0524; H01L 31/02327
USPC 136/246; 136/259; 136/256

(57) ABSTRACT

A solar cell assembly, including an electric-optically transducing layer, an electrically conducting layer, and an electrically insulating layer positioned between the electric-optically transducing layer and the electrically conducting layer. The assembly includes a hydrophobic layer, a dielectric layer positioned between the electrically conducting layer and the hydrophobic layer, and a liquid microdroplet lens positioned in contact with the hydrophobic layer. The electrically conducting layer, the electrically conducting layer, the hydrophobic layer and the dielectric layer are substantially optically transparent. The liquid microdroplet lens may optionally be contained within a substantially optically transparent lens compartment.

### CROSS-REFERENCE TO RELATED APPLICATIONS

This patent application is a continuation-in-part of and claims priority to co-pending U.S. patent application Ser. No. 13/312,308, filed on Dec. 6, 2011 and claims priority to PCT application serial no. US11/63477, filed on Dec. 6, 2011, both of which claim priority to then co-pending provisional patent application Ser. No. 61/420,535, filed on Dec. 7, 2010.

### TECHNICAL FIELD

The disclosed technology relates generally to the field of digital microfluidics, and, more specifically, to lenses that enhance the capture of solar energy.

### BACKGROUND

Reducing the cost of solar electric power generation is one route to increasing the penetration of solar power in renewable energy systems. Reducing the cost may require smaller devices with high-performance energy conversion. To increase the efficiency of energy production, an effective technique is the light throughput increment. What is needed is an innovative controllable acceptance angle light throughput interface that enhances the efficiency of solar cells. The present novel technology addresses this need.

### BRIEF DESCRIPTION OF THE DRAWINGS

FIG. 1 graphically illustrates the contact angle of liquid droplets on a substrate in a high-wetting orientation and a low-wetting orientation.

FIG. 2 graphically illustrates the contact angle of liquid droplets on a substrate in a high contact angle and a low contact angle.

FIG. 3A is a side elevation cutaway view of a solar cell assembly according to a first embodiment of the present novel technology.

FIG. 3B is a side view photomicrograph of FIG. 3A.

FIG. 3C is a top view photomicrograph of FIG. 3A.

FIG. 4 is a graphic illustration of droplet size vs. energy generation for the cell assembly of FIG. 3.

FIG. 5 is a graphic illustration of microfluidic lens size on solar cell voltage for the cell assembly of FIG. 3.

FIG. 6 graphically illustrates the output of cells using microfluidic lens arrays vs. cells without microfluidic lens arrays for the cell assembly of FIG. 3.

FIG. 7 graphically illustrates microfluidic lens contact angle vs. voltage output for the cell assembly of FIG. 3.

FIG. 8 schematically illustrates an array of solar cells according to a second embodiment of the present novel technology.

FIG. 9 schematically illustrates solar cells according to the embodiment of FIG. 3 and/or 8 as configured to scatter incident light and to concentrate incident light, respectively.

FIG. 10 schematically illustrates the array of FIG. 8 having lenses composed of oil.

FIG. 11 schematically illustrates an array of solar cells wherein the lens fluid may be circulated to cool the solar cells, according to a third embodiment of the present novel technology.

FIG. 12 schematically illustrates the plumbing of a solar cell of FIG. 11.

FIG. 13 schematically illustrates concentration of sunlight by the array of FIG. 8 with the Sun at different positions relative to the array.

FIG. 14 schematically illustrates the use of voltage to change the shape of the lens of the cell of FIG. 12.

FIG. 15 schematically illustrates an example of an electrowetting lens compartment according to one embodiment of the disclosed technology.

FIG. 16 is a top plan view of the lens compartment shown in FIG. 15.

FIG. 17 a is a side view of the lens compartment of FIG. 15 with a first voltage applied.

FIG. 17 b is a side view of the lens compartment of FIG. 15 with a second voltage applied.

FIG. 18 schematically illustrates one possible configuration of lens compartments according to one embodiment of the disclosed technology.

### DETAILED DESCRIPTION

For the purposes of promoting an understanding of the principles of the novel technology and presenting its currently understood best mode of operation, reference will now be made to the embodiments illustrated in the drawings and specific language will be used to describe the same. It will nevertheless be understood that no limitation of the scope of the novel technology is thereby intended, with such alterations and further modifications in the illustrated device and such further applications of the principles of the novel technology as illustrated therein being contemplated as would normally occur to one skilled in the art to which the novel technology relates.

The phenomenon of electrowetting provides opportunities to manufacture variable and controllable lenses specifically for solar cells, enabling a wide acceptance angle device with small physical dimensions, which may be used in all weather conditions. Increased energy may be harvested from solar cells when the light intensity is not optimal. Preliminary results demonstrate about 78% increase in the energy generation of the cells in low light intensity conditions.

The present novel technology broadly affects photovoltaic energy harvesting by enabling a fully controllable embedded optical throughput interface. The interface enables the use of liquid lenses of variable shape and orientation to direct incident sunlight as desired onto an electro-optically transductive substrate to maximize power generation. Solar thermal energy harvesting is directly enhanced.

Energy generation of solar cells is a function of the intensity of light to which they are exposed to during daytime. Typically, as the sun's position changes in the sky, the amount of harvested energy will change and reaches maximum when the sun is directly overhead. A transformative technique enables the solar cells to approximate their maximum power production level all day long and under all weather conditions without the need for expensive solar position controllers and power electronic converters. The present novel technology relates to the application of digital electrowetting lenses 10 and advanced control algorithms to achieve continuous control of light beam intensity onto solar cells and photovoltaic panels 15. When a sufficiently high potential is applied across a hydrophobic dielectric layer 20, the phenomenon of electrowetting allows the contact angle of a droplet 10 on that layer to change accordingly. The solar cell assembly 35 may also include an additional dielectric layer 40 positioned between the hydrophobic layer 20 and the electric conducting layer 30. 25, 30, 40 thin enough to be substantially transparent. Typically, the assembly 35 is optically transparent, either B9 selection of inherently transparent materials and/or fabricating the layers 20, Therefore, the droplet defines a controllable focal point lens 10.

Employing digital electrowetting lenses 10 benefits solar electric energy generation by: 1) increasing the cell's acceptance angle; 2) controlling energy generation in various environmental conditions such as partial shading; 3) increasing the cell's energy density; 4) controlling the cell's operating point temperature; and 5) enabling Optical Maximum Power Point Tracking (OMPPT); and 6) using this technique for thin and thick film solar cells.

Microfabrication processes allow for the positioning of electrowetting lenses 10 onto transparent structures or substrates and electrically conductive material layers 25. Advanced control techniques that adjust the focal point of electrowetting lenses 10 to maximize power generation and maintain an optimum operating temperature of the assembly 35 may be incorporated. The photovoltaic layer 15 and the lens 10 are integrated into the assembly 35 and the energy generation enhancement is measured in several applications of mobile lenses 10.

The present novel technology incorporates and combines the efficiency enhancement in solar power generation, embedded optical maximum power tracking techniques with reduced size power electronic converters, temperature management of the cell, and digital electrowetting phenomena with application in solar power.

Solar cells operate to transduce light energy into electrical energy. These cells typically utilize PN junctions made in semiconductor materials (typically doped silicon) as the photovoltaic material that generate electric current when excited by photons. Incident sunlight intensity directly governs the number of released electrons and, therefore, the amount of current generated from solar cells. Hence, the energy generation of all types of solar cells may be enhanced by accurately collecting and concentrating a controlled beam of light onto the cells. The power generation may be increased in two ways: 1) by enhancing the light absorption in a wide acceptance angle provided by electrowetting lenses and/or 2) by reducing the light losses as described below.

Effects of a Controllable Lens on Acceptance Angle and Efficiency

The solar-to-electric power conversion ratio is limited by the optical throughput of the device. However, illumination non-uniformity negatively affects the electrical power generation because of reduced solar cell efficiency. Sometimes, the illumination on a solar cell becomes non-uniform for incident angles less than the acceptance angle. Therefore, the effective acceptance angle may be defined as the misalignment beyond which solar cell energy production falls below an acceptable level. The optical throughput is the highest for an incident angle of zero degrees. It remains high for a finite range of incident angles and then decreases for angles larger than the acceptance angle. The current technologies to improve the efficiency of solar cells may be limited to the application of light trapping structures, the utilization of the full solar spectrum, and the technique of achieving wide acceptance angles. Multi junction and tandem structures have been proposed to fully utilize incident solar energy by more efficiently absorbing the solar spectrum and/or recycling the reflected incident light for absorption.

Solar concentrators are often utilized to increase the acceptance angle of the cells and, therefore, increase the efficiency of power generation. The optical throughput for the concentrator is measured as a function of the angle between the incident sunlight and the optical axis of the concentrator. Fixed light concentrators such as Fresnel Lens, Prismatic Covers, Stretched Lens Array (SLA), and Terrestrial Concentrators have been used to increase the optical throughput of the cells. These techniques increase the amount of power generated from the cell. However, the acceptance angle increment is limited, and the focal point of the lens remains uncontrolled.

Electrowetting on dielectric (EWOD) phenomena has been successfully used in many applications ranging from lab-on-a-chip to digital microfluidics in devices like liquid lenses. The present novel technology incorporates EWOD digital microfluidic lenses 10 into solar cells assemblies 35 to increase the light throughput by increasing the effective acceptance angle and the efficiency of the power conversion the solar cells 35.

Effects of a Controllable Lens on Loss Minimization

The performance of commercially available cells is about 12%, and can reach 20% when the best material and technology are used. This low efficiency is the result of several losses in the solar cell including 1) reflection loss; 2) transmission photons passing through the cell without colliding with an atom in the cell; 3) quantum loss, which is the result of photons with energy lower than the band-gap energy of silicon with efficiency of about 23%; and 4) collection loss, which is the reabsorption of the released electron due to high energy photons with efficiency of about 90%. To reduce the surface reflectivity of the device and increase the number of trapped photons, several techniques exist such as: 1) the application of nanowires; 2) the use of periodic textured surfaces; 3) the use of transparent conductive oxide (TCO) coatings; and 4) the use of random rough surfaces and the design of surface plasmon.

Effects of a Controllable Lens on Thin Film Solar Cells

The solar electric power industry has experienced extraordinary annual growth rates of over 30% in the last few years following improvements in the efficiency and the demand for alternative energy resources. However, for large-scale implementations, the cost of photovoltaic modules still has to be significantly reduced. One approach that promises a significant cost reduction is thin film solar cells. Thin film cells are based on hydrogenated amorphous or microcrystalline silicon and alloys of the same. For thin-film silicon solar cells, the Si absorber has a thickness of approximately only a few micrometers and is deposited on glass, ceramics, plastic, or metal substrates for mechanical support. However, because of the relatively poor light absorption and high bulk and surface recombination, the efficiencies of thin-film cells are low compared to those of wafer-based silicon cells.

For all thin-film silicon solar cells, scattering at interfaces between neighboring layers with different refractive indices and subsequent trapping of the incident light within the silicon absorber layers is crucial to gain an increased transduction efficiency. As a result, in a thin film with a thickness of not more than several microns, incoming light will not be completely absorbed during one single pass. On the other hand, to minimize processing time and reduce light-induced degradation of the amorphous Si, the absorber layer thickness is desired to be as thin as possible. Because of the very small thicknesses of thin-film solar cells (a few microns), standard methods of increasing the light absorption, such as surface texturing, cannot be used. Hence, optical absorption inside the silicon layers has to be enhanced by increasing the optical throughput of solar radiation.

A controllable lens 10 can adjust the light intensity with the absorption coefficient of different materials to increase the energy production. Applied with light trapping textures, the EWOD digital microfluidic lenses 10 provides a high throughput source of light for state-of-the-art, low-cost, highly efficient solar cells 35. One liquid lens 10 can change its curvature to provide confocal and concave lenses, depending upon the amount of applied voltage. Therefore, liquid lenses 10 can concentrate the light beam on the focal point of the regular photovoltaic layers 15 or scatter the beam on the thin film photovoltaic layer 15 to increase the absorption rates.

Electrowetting and Controllable Digital Microfluidic Lenses

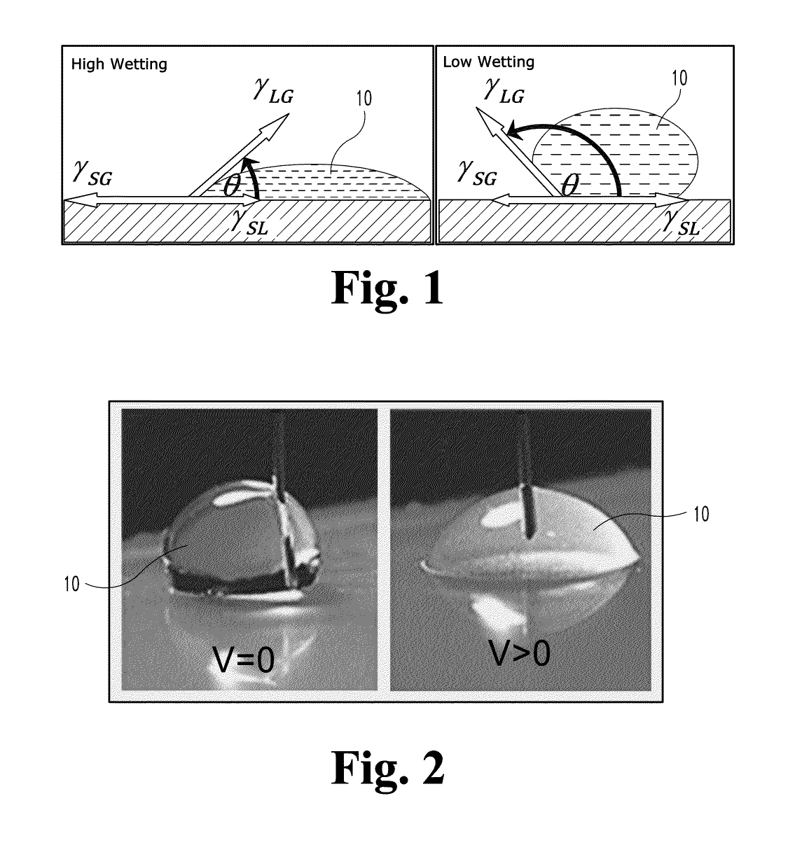

Microfluidic lenses 10 may be manufactured either as a single droplet 45 of a preferably electrically conductive liquid on digital electrowetting contacts 30 as the first, typically electrically conducting, liquid 55 or by using two immiscible liquids 50 of the same density (e.g. salt water and insulating oil as the second, typically electrically insulting, fluid 60) on a dielectric layer. In both cases, according to the Young Equation, the contact angle of a droplet 10 on top of a surface 20 is expressed as a function of the surface tensions that the droplet 10 has with the surrounding gas and solid surfaces. The angle may be found as:

$$cos θ = \frac{{γ}_{SG} - {γ}_{SL}}{{γ}_{LG}}$$

where γ_{SG}, γ_{SL}, γ_{LG}, are the surface tensions of the Solid-Gas, Solid-Liquid, and Liquid-Gas respectively. FIG. 1 shows the contact angles used in the Young Equation.

The contact angle 70 of the droplet 10 may be controlled by applying voltage to the conductive liquid 55. The Young-Lippmann Equation shows the effect of the voltage in controlling the contact angle 70 or electrowetting on the dielectric 40 EWOD as:

$$cos θ = \frac{{γ}_{SG} - {γ}_{SL} + \frac{1}{2} {CV}^{2}}{{γ}_{LG}}$$

where C is the capacitance per unit area in the region of contact between the dielectric layer 40 and liquid 55, and V is the applied voltage to the droplet 10 on the dielectric layer 40.

This equation describes how the contact angle 70 decreases as the applied voltage from a voltage source 75 increases. The contact angle 70, and consequently the curvature of the droplet 10, which acts as a lens 10, may be controlled very precisely by applying appropriate voltages. FIG. 2 shows the effect of EWOD at different voltages and controls of the angle 70.

Necessity and Benefits of Digital Microfluidic Lenses in Solar Cells—As mentioned above, the integration of digital microfluidic lenses 10 with photovoltaic panels 15 brings many advantages: 1) simultaneous cost reduction and efficiency enhancement; 2) the operating temperature of the device 35 will be controlled from the surface of the cell 35 through microfluidic channels; 3) increasing and controlling the acceptance angle of the device provides a uniform light distribution on the cell 35, and therefore, the efficiency of the cell 35 is increased; and 4) energy generation may be controlled and maximized without the need for large power electronic converters.

The future envisioned for controllable solar power generation units involves many distributed grid connected or standalone units totaling megawatts of power. This novel technology benefits solar power plants, the public, the environment, and the local and federal government.

Benefits to Solar Power Plants

A controllable solar cell assembly 35 enjoys reduced cost while efficiency is maximized by utilizing the light throughput control units 90. Since the operating temperature of the cell assembly 35 is controlled from the surface, the lifetime of the cell 35 may be significantly increased. The need for a sunlight-tracking system and expensive equipment to maintain cell assemblies 35 and multiple cell arrays 95 facing toward the sun is reduced, since the lenses 10 may be controlled to maximize the light intensity at skewed angles. The effects of shading on the solar panels is likewise minimized and the energy generation is enhanced.

Benefits to the Public as Future Microgeneration Unit Owners

The incentives provided by governments, along with the highly efficient and affordable solar power generation units, promotes the application of smaller-sized plants in households and commercial applications. This promotes green energy generation at high-level standards.

Benefits to the Local and Federal Government

Expanding the highly efficient solar energy generation units provides the local government and federal agencies the capability to forecast microgeneration power growth in their energy markets and strategic energy plans. In addition, the cost of operation and capital investment for solar cell assemblies 35 is significantly reduced.

The present novel technology relates to 3 main areas: 1) uniform illumination, light capturing and throughput enhancement, and uniform illumination enhancements; 2) adaptive optical adjustment in thin film and thick film solar cells; 3) optical sun tracking (OST) and optical maximum power point tracking (OMPPT) in solar cells.

Considerations for the Acceptance Angle Increment

1) The ability to provide a wide acceptance angle that covers misalignments of several degrees; 2) the ability to conduct electric current through the transparent materials used in the microfluidic lenses 10; 3) the ability to reject the heat and control the temperature of the solar cell assembly 35 from the surface of the cell assembly 35; and 4) the ability to increase the efficiency of the cell assembly 35.

Considerations for the Adaptive Optical Adjustment for Maximum Efficiency

1) The ability of the microfluidic lens 10 to adjust to the light concentration for thin-film and thick-film solar cell assemblies 35; 2) the ability to control the focal point and lens curvature from a concentrated beam to a scattered light and to adjust it with the materials used in the solar cell assembly 35; and 3) the ability to maintain minimum light losses and full spectrum conductance.

Considerations for Optical Sun Tracking and Optical Maximum Power Point Tracking (OMPPT)

1) The ability to track the sun by skewing the curvature of the lens 10 and without using the mechanical controls of the solar panel array 95; 2) the ability to maximize the power generation of the cell assembly 35 by adaptive adjustment of the lens focal point; 3) the ability to increase the lifetime of the cell assembly 35 by adjusting the temperature; 4) the ability to study the limitations of the contact angle and focal point to maximize power generation of the cell assemblies 35; and 5) the ability to consider the lens focal point hysteresis in the process of controlling the microfluidic lenses 10.

The novel technologies for high power solar cell assemblies 35 also have military and commercial applications: 1) a wide acceptance angle with light throughput interface from the lens 10 to the electro-optic transduction layer 15; 2) liquid-liquid droplet lens 10 technologies for high-power micro solar electric and micro solar thermal units; 3) surface heat rejection technology in solar cell assemblies 35; 4) adaptive adjustable Optical Maximum Power Point Tracking technology for in-transit solar array 95 applications, such as military army, solar airplanes, submarines, vehicles, and other mobile solar chargers; and 5) the optical sun tracking system will be enabled by a skewed microfluidic lens 10 technology.

A series of tests has been conducted to prove the concept of using microfluidic lenses 10 to enhance energy generation in solar cell assemblies 35. The preliminary results, conducted at the Purdue School of Engineering and Technology, demonstrate a 78% increase in the energy production from solar cell assemblies 35. The details of these results follow below.

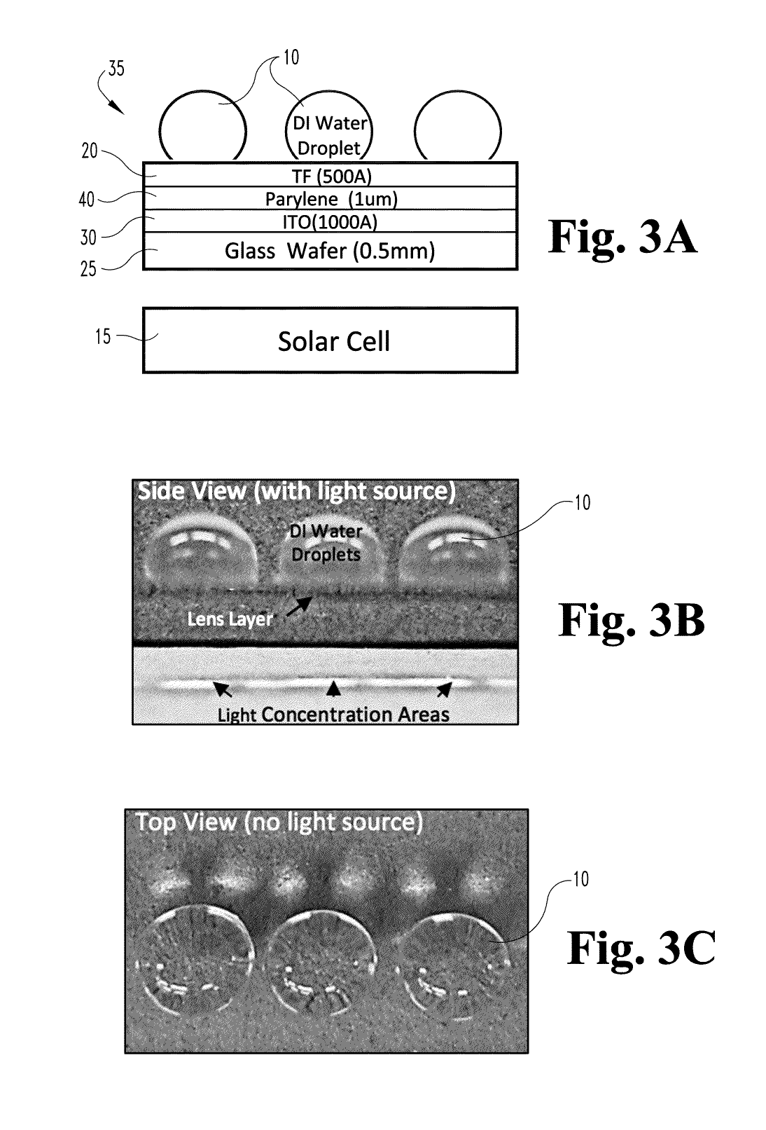

Lens Compartment—A prototype digital electrowetting system was designed and manufactured. The digital electrowetting system has several layers 15, 20,25,30, 40 naming a 1000 Å ITO 30 on 0.5 mm thick glass wafer 25. The sandwich wafer 30 was coated by 1 μm Parylene as a dielectric layer 40 and a 500 Å Teflon layer to create a hydrophobic surface 20. This device 35 was used for fixed droplet sizes for a wetting action. FIG. 3 shows the prototype digital electrowetting device 35.

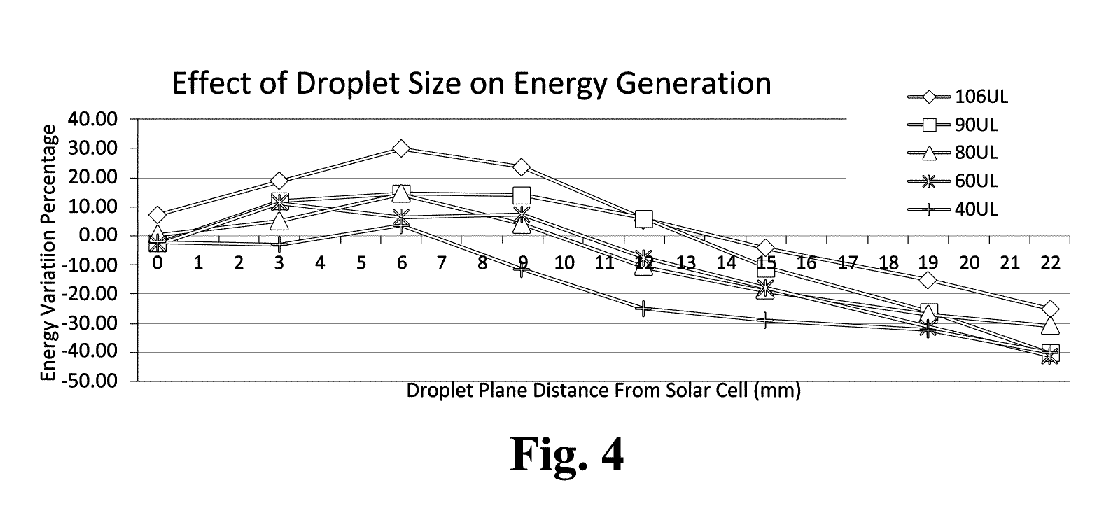

Experimental Results—The purpose of the experiment (conducted at the Purdue School of Engineering and Technology) was to increase the energy generation of a solar cell assembly 35 by using droplet lenses 10 spaced a distance from the photovoltaic layer 15 (schematic in FIG. 3). The effects of the energy generation enhancement are shown in FIG. 4. Several droplets 10 with various volumes were tested to illustrate the best lens 20 size for the solar cell assembly 35. The contact angle 70 of the DI water droplet 10 on the hydrophobic surface was about 120°. As the figure shows, increasing the volume of the droplet 10 increased the energy generation of the solar cell assembly 35. The percentage of the energy generation increase from using microdroplet lenses 10 on the solar cell assemblies 35 is a function of the lens plane distance from the photovoltaic layer 15 or focal point. This shows the effects of in- and out-of-focus lenses 10. Smaller sized droplets 10 could still enhance the energy generation, but at a lower percentage. The energy generation decreased when the microdroplet lenses 10 were out of focus at distances above 15 mm from the photovoltaic layer 15. The highest energy generation was obtained with droplets 10 that had a volume of 106 μL. The number of droplets 10 was limited to three by the available space on the solar cell assembly 35 and the minimum distance between two adjacent droplets 10. The minimum power increment was obtained with six droplets 10 with a volume of 40 μL.

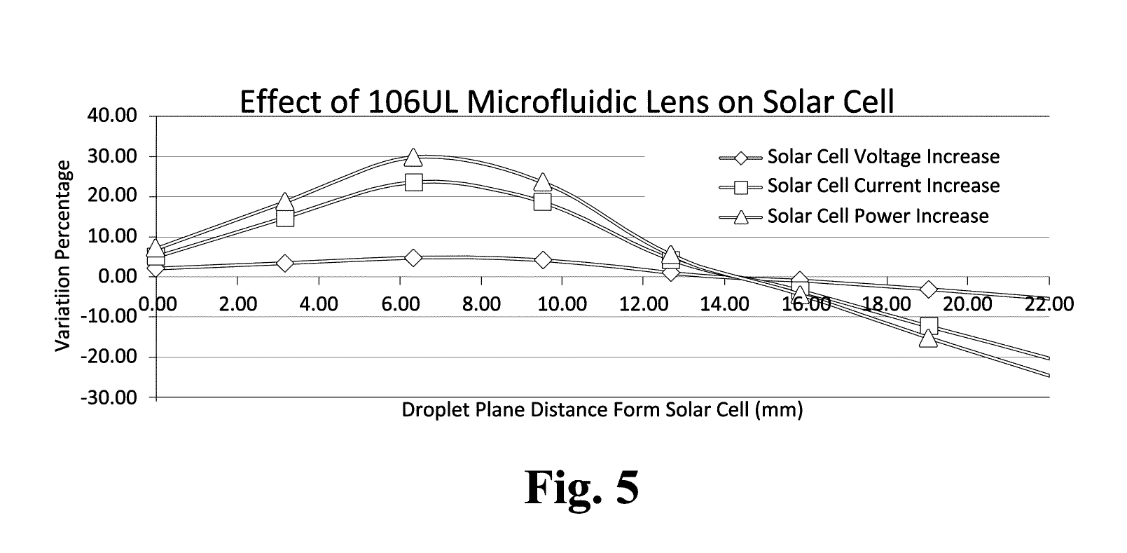

FIG. 5 illustrates the percentage of the voltage, the current, and the power increase when three microdroplet lenses 10 of 106 μL volume each were used. This figure also demonstrates about 29% energy generation enhancement by controls of the focal points in electrowetting of the solar cell lenses 10.

Controllable Electrowetting Lens

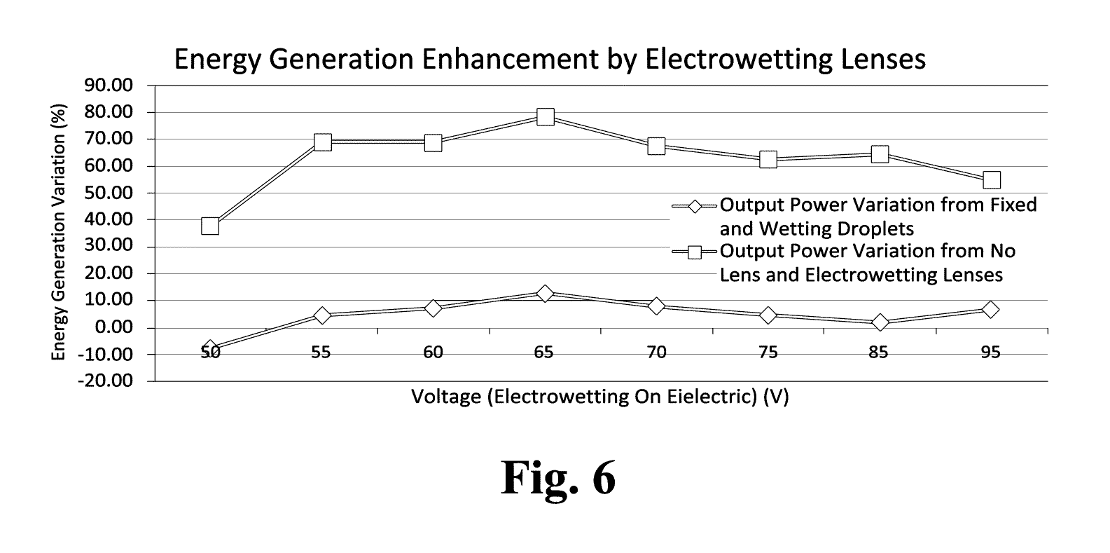

Application of controllable lenses 10 in energy generation enhancement is shown in FIG. 6. By increasing the voltage, the amount of energy generation is increased as the lens 10 focuses more light at the photovoltaic layer 15. In-focus condition increases the light throughput of the lens compartment. A 78% increase in energy was achieved from the solar cell assembly 35 under the same light condition without any lens 10. The energy generation enhancement could reach 14% increase from when a fixed (uncontrollable) lens 10 was used as a light concentrator. This technique can also provide a wide range of control over the operating temperature of the solar cell assembly 35.

Microfluidic Lens Design and Droplet Optimization

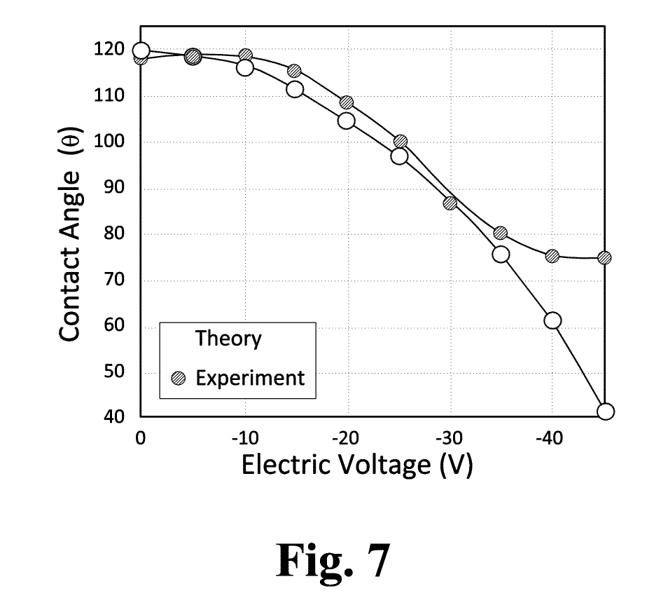

The design and manufacturing of microfluidic lens-enhanced solar panels 35 began with a single liquid droplet lens 45 and was improved to liquid-liquid droplets 50 to provide a wide range of lenses 10 and utilize them for different solar cell assemblies 35. In the design and manufacturing of these lenses 10, several details are considered. Since solar panels are mounted on tilted surfaces (to maximize the light capturing) the effects of gravity on the liquid lenses 10 should be reduced. Two immiscible liquids 55, 60 of the same density, such as water and oil, can suppress any optical distortion that gravity imposes on the liquid-liquid interface. This enables the lens 50 to be used omnidirectionally. The lens 50 may be operated by applying voltages to the conducting liquid 55. To minimize the optical perturbation in the interface of the two liquids 55, 60, the immersed droplet 60 is preferred to be an insulating material, such as oil. To increase the precision of the liquid lenses 50, the immersed droplet 60 is typically located at the center of the lens 50. Alternately, in the absence of centering techniques, the droplet 60 can freely move in transverse directions. The contact angle 70, and therefore the focal point of the liquid lens 50, is accurately determined by the Young-Lippmann equation. However, in extreme conditions, such as when the conductance of the conductive liquid 55 decreases, this equation cannot accurately predict the contact angles 70. Experimental measurements and theory predictions of contact angles 70 in a water droplet 10 are shown in FIG. 7. Typically, additional sources of ions are added to the conducting liquid 55 to prevent saturation. The main source of ions may be provided by dissolving salts into the conductive liquid 55. As the contact angle 70 variation saturates, the acceptance angle of the lens 50 is reduced.

Techniques for Centering the Liquid Droplets

Centering of the liquid-liquid interface may be achieved by several techniques. Changing the thickness of the dielectric layer 40 provides an electric field gradient that centers the liquid droplet 60. Alternately, fabricating specially shaped electrodes 35, 100, such as a ring type, provides centric forces. The geometry of the supporting structure, such as an inward cone, a cylindrical edge, and a toroid shape, may also provide a centering structure.

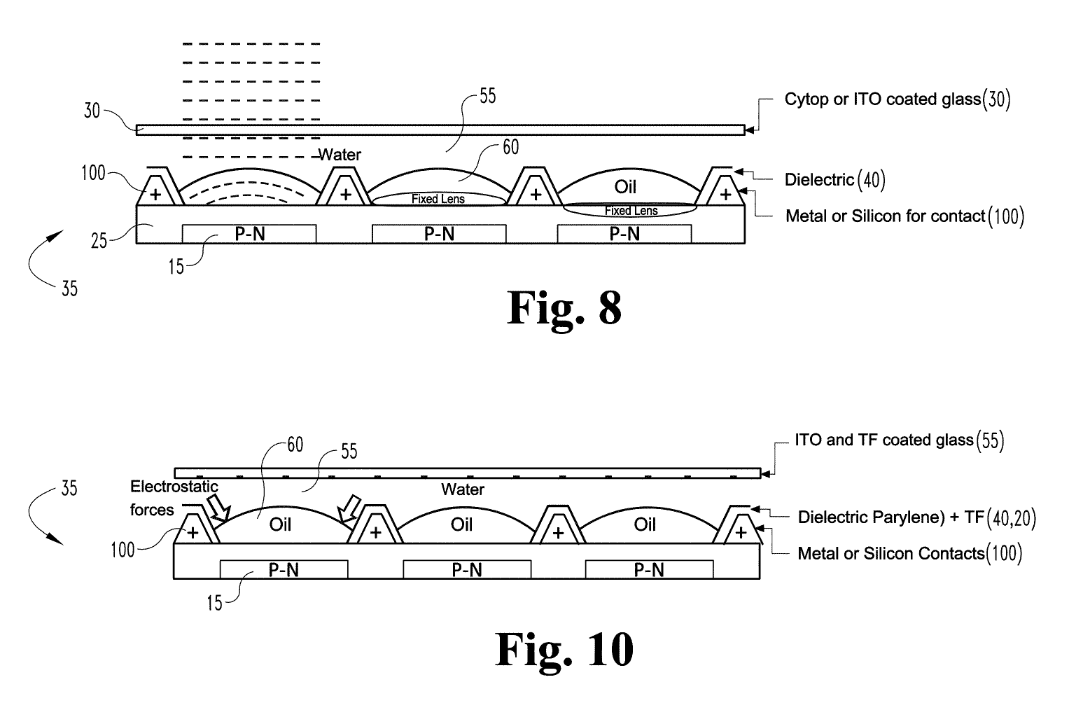

The present novel technology relates to various designs for microdroplet lens shapes to identify the best energy enhancement configurations. Different shapes may be formed, such as half-cylindrical, semispherical, or two-curve confocal-concave lenses 50. FIG. 8 illustrates some different lens configurations. An effective way for centering of the lens may be the use of a hydrophilic patch in the center of the lens 50 to keep the oil droplet 60 in place.

Concentrating and Scattering Properties of Microfluidic Lenses

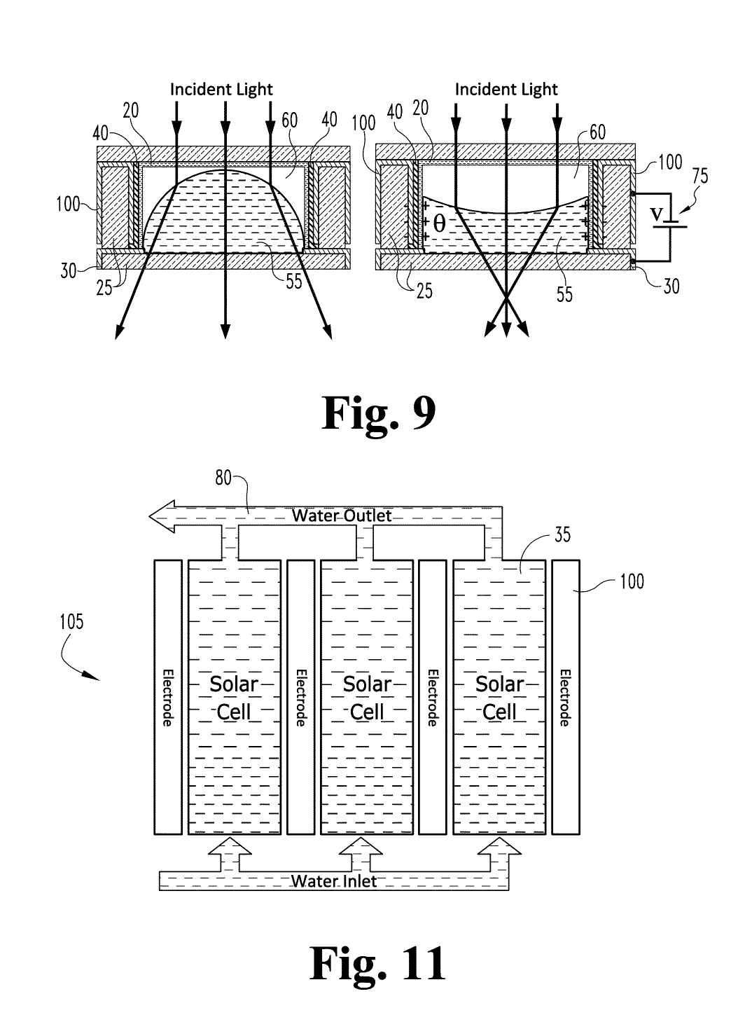

A cylindrical lens 50 is shown with concentrating (left) and scattering (right) conditions in FIG. 9. As the electrode 30 across the dielectric layer 40 is energized, the surface is wetted and the contact angle 70 of the conducting liquid 55 changes. Therefore, the initially scattering lens 50 becomes a controllable focal point lens 50. The light scattering condition is very useful for thin-film solar cell assemblies 35, where the efficiency of the assembly 35 is increased by the light-trapping material and structures. Light scattering conditions distort the light in several directions and increase the energy generation of the thin-film cell assemblies 35. Concentrating operations of the lens 10 may be used in regular and thick-film solar cell assemblies 35. The amount of energy may be controlled by simply re-adjusting the focal point of the light beam in and out of the solar cell plane. FIG. 9 shows the lens 10 operation in two concentrating and scattering conditions.

A mask for different layers of material, microfabrication, material selection, and manufacturing of microdroplet lenses 10 was designed and manufactured at the Purdue University Brick Nanotechnology Center. The lens diopter and the energy generation enhancement is the major evaluation criteria.

Droplet Size Optimization

Energy generation enhancement is a function of the size of the droplet 10. Proper size of the droplet 10 and optimization is based on the type of the solar cell, and the type of liquid that is used in the lens compartment. In preliminary results, DI water droplets 10 of a volume of 106 μL result in power generation enhancement of about 78%.

Solar Cell and Light Capturing Interface Integration

As the Lens Compartment is designed and manufactured, the main issue will be the integration of the photovoltaic layer 15 and the lens 10 in one fixture to hold them in the proper position. One example of this fixture is shown in FIG. 10. The fixture provides the proper connection for the photovoltaic contacts and the lens electrodes 30. The fixture also provides enough insulation for the solar cell and the lens contacts 30, 100. In addition, the lens compartment houses the microfluidic network 80 to remove the heat from the surface of the cell assemblies 35. This fixture is designed to hold all the proper piping and insulating contacts in one structure. The contacts 30, 100 for the lens 10 may be made with metal, silicon, transparent conductive material, or the like, to maximize the light throughput. The fixture itself may be micro-machined and made of insulating structural material, such as epoxy glass resin or the like.

Surface Heat Rejection Network Design and Fabrication

Photovoltaic layers 15 directly convert the sun's energy into electricity. The operating temperature of the cell assembly 35 increases as the incident sunbeam intensity increases. However, operation at elevated temperatures reduces the lifetime and amount of the power generated by the cell assembly 35. Therefore, cooling the photovoltaic layer 15 is desirable to maintain higher efficiencies and a longer lifetime for the cells. Previously, cooling occurred from the back of the solar panel and from the airflow on the surface. While the use of microfluidic lenses 10 can cause the operating temperature to increase even further, the microfluidic channels 80 themselves may be utilized to provide a microcirculation and cooling system 105 for the cell to conduct or remove heat from the surface of the photovoltaic layer 15.

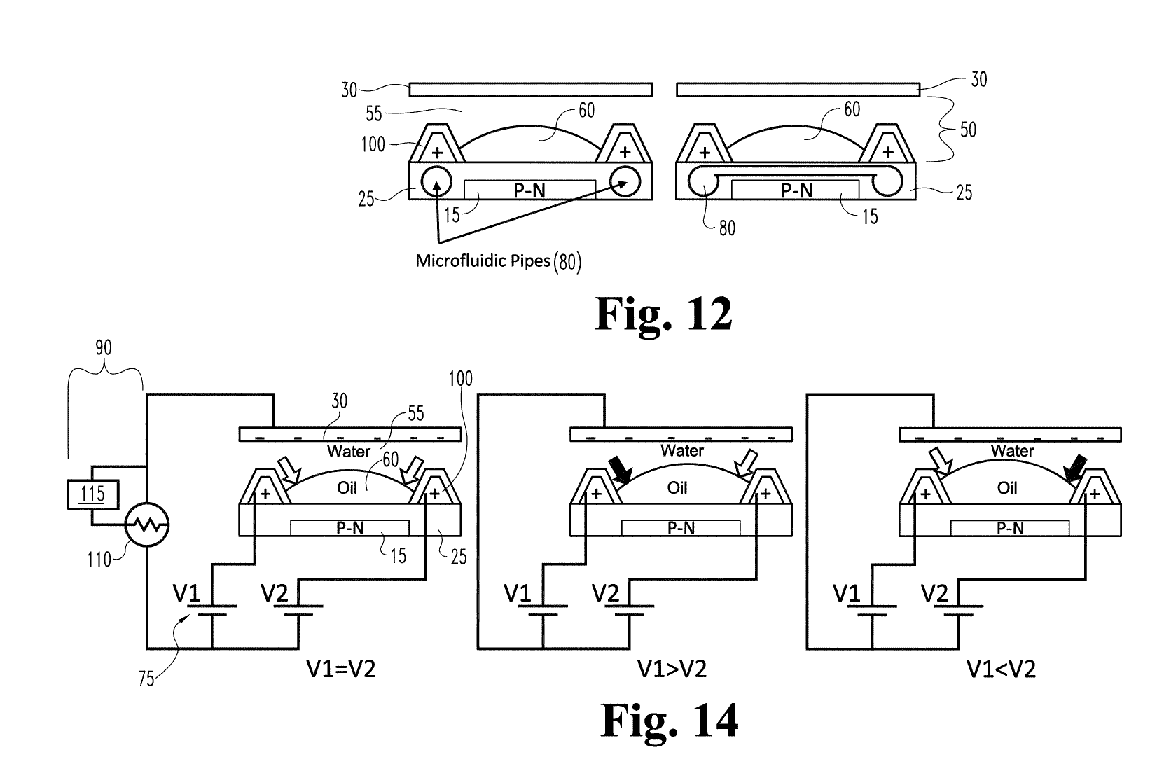

Microfluidic lenses 10 provide a network of circulating liquid that can help in rejecting the heat from the surface of the photovoltaic layers 15 and keep the device 35 in lower temperatures for more energy production and longer lifetime operations. Several techniques and microfluidic network designs may be used to effectively transfer the heat away from the solar cell assemblies 35. The main approach is to have the conducting liquid 55 circulate from a collection of solar cells 35 and remove the heat from the surface of the solar cells 35. Several liquids including coolant liquids were experimentally tested. FIG. 11 shows the application of microfluidic and the heat gradient in the surface of the solar cell assemblies 35. FIG. 12 illustrates two typical designs of manufactured cooling pipes 80.

Optical Sun Tracking Algorithm Development

Photovoltaic cell energy generation is extremely sensitive to shading, such as when incident light is blocked by an intervening object. Since all cells are connected in series and parallel, partially illuminated cells prevent the current flow throughout the system. To prevent this effect, manufacturers have installed bypass diodes. These diodes bypass the off (shaded) cells and let the current flow. This effect significantly reduces the power generation of the cell. Diodes can prevent the partial shading effect; however, when the entire area of the cell is covered, the power generation is minimized.

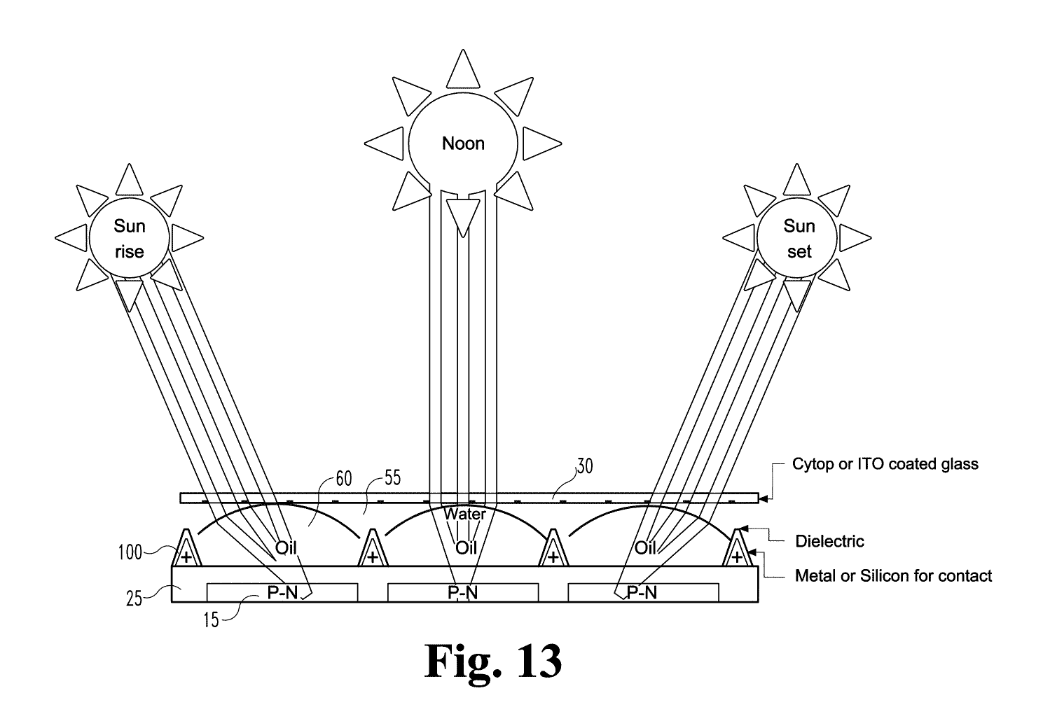

To increase power generation in both partial and full shading conditions, the lens compartment can adjust the focal point of the microdroplets 10 by changing the contact angles 70 of the droplets 10. More energy may be produced if more light is concentrated on the photovoltaic cell 15. The ideal condition is that all lenses 10 be individually accessible to prevent the shading effects and maintain high efficiency in all conditions. This system can also be used at different times of the day when the sun rises or sets (FIG. 13).

Control algorithms that maximize power generation of a solar cell assembly 35 by skewing the lens curvature to track the sun in the sky are typically utilized. This brings the benefit of a soft control on the acceptance angle. Optimization of algorithms to control one individual solar cell assembly 35 or several cells in array on the panel 95 is utilized. The lens rotation conditions are simulated in FIG. 14. As the figure illustrates, by controlling the voltage at the side contacts of the lens 10, the focal point of the lens 10 will rotate to adjust to the sun's position in the sky. This maximizes the power generation of the solar cell assemblies 35 without the need for mechanical equipment to rotate the arrayed solar panels 95 toward the Sun.

Optical Maximum Power Point Tracking Algorithm Development

Solar panels in large scale arrays typically face the Sun in an effective direction to absorb the most energy available. As the position of the Sun changes in the sky, heavy panels are moved with electric actuators and their angle is re-adjusted to increase power generation. In addition, the electric current and the voltage of the solar cells, due to the limited and uncontrolled intensity of the exposed light, require continuous adjustment by power electronic converters. This requires extra control algorithms and power converters to increase the system power generation at a fixed light intensity. However, if the intensity of the light is controlled, the amount of electric current and voltage can therefore be controlled to maximize the output power of the cell and decrease the complexity of the control system.

The present novel technology includes control algorithms that seek the maximum power generation of the solar cells at different light conditions and Sun incident angles. The cell assembly 35, and arrays 95 thereof, therefore, will have a built-in Optical Maximum Power Point Tracking (OMPPT) unit that maximizes the output power of the cell assembly 35 at all conditions. These OMPPT units typically include a voltage source 75 in electric communication with the electrodes 30, 100, a current sensor or ammeter 110 operationally connected to the photovoltaic portion(s) 15, and a microprocessor 115 operationally connected to the voltage source 75 and to the ammeter 110. The microprocessor 115 is typically programmed with the above equations and mathematical relationships such that the microprocessor 115 may optimize lens shape through voltage source 75 output in response to ammeter 110 signals received to maximize light intensity on the photovoltaic portions 15 and thus current output. The microprocessor 115 may also be programmed to vary lens 10 shape to track solar movement to maintain lens 10 focus for a stationary assembly 35.

Electrowetting Lens Compartments

Alternative embodiments of the disclosed technology include one or more lens compartments to contain the fluid(s) which comprise the electrowetting lens and/or lenses as previously described. Lens compartments could allow for the adaptation and use of lenses according to the disclosed technology to a variety of solar cell applications, allow for the use of standardized lens configurations in a variety of solar cell applications (such as a lens configuration which could be used in both thick and thin film solar cells), and could make lenses which are more easily assembled, transported, installed, and repaired by containing the lens fluid(s) inside a lens compartment.

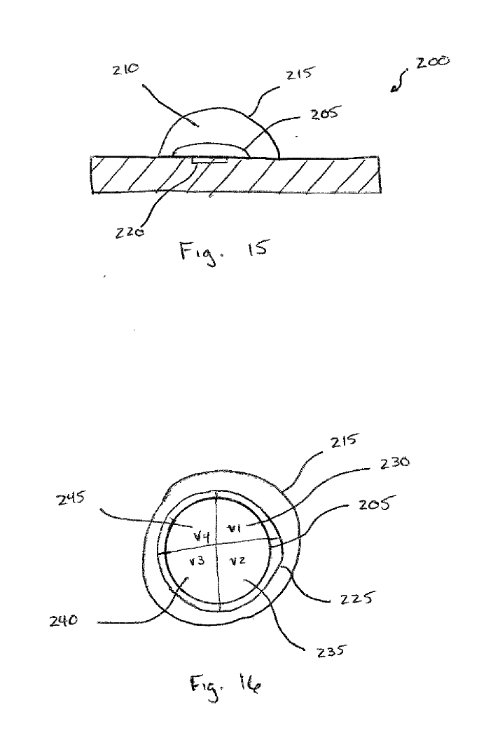

One example of a liquid electrowetting lens contained inside a lens compartment is shown in FIGS. 15-16. In this particular example, a lens assembly 200 having a microdroplet lens 205 disposed within a lens compartment 215 is shown. The lens compartment 215 is made from a substantially optically transparent material. The lens compartment material may be flexible or rigid depending on the desired application. In one example, the lens compartment is made from a flexible material and formed into a generally confocal lens. Other shapes such as semi-cylindrical, ovoid, cubes, and irregular lens compartment shapes may also be used.

The space 210 within the lens compartment not occupied by the microdroplet 205 is filled with a suitable fluid. In this particular example, the fluid occupying the remaining space 210 is air. In other examples, the remaining space 210 may be filled with oil or some other suitable fluid which is immiscible with and has the same density as the microdroplet fluid. The microdroplet lens 205 is in contact with one electrical contact 220. The lens compartment 215 is disposed above one or more contacts having the opposite polarity of electrical contact 220. In the example shown in FIGS. 15-16 the lens compartment 215 is suspended over an array 225 of four electrical contacts 230, 235, 240, 245 which are generally wedge-shaped and electrically isolated from one another. In other examples, the contacts differ in number and/or shape. The electrical contact array 225 is configured and arranged such that current may be applied selectively to one or more of the four electrical contacts 230, 235, 240, 245 as desired. When a voltage is applied to the contacts 230, 235, 240, 245, the applied force will decrease the contact angle and force the microdroplet lens 205 flat against the bottom of the lens compartment thereby changing the focal point of the microdroplet lens 205.

By selectively applying current to contacts 230, 235, 240, 245 the shape, and thereby the focal point, of lens 205 may be altered as desired. For example, if a greater current is passed through contacts 230 and 245 than through contacts 235 and 240 a lens shape similar to that shown in FIG. 17a may be produced. If conditions are reversed and a greater current is passed through contacts 235 and 240 than through contacts 230 and 240 a lens shape similar to that shown in FIG. 17b may be produced. Selective application of current to contacts allows for the focal point of the microdroplet lens to be altered so as to better focus light as the sun moves during the day or as the lens assembly moves relative to the sun (for example, if the assembly is attached to a moving vehicle such as a ship or other vehicle).

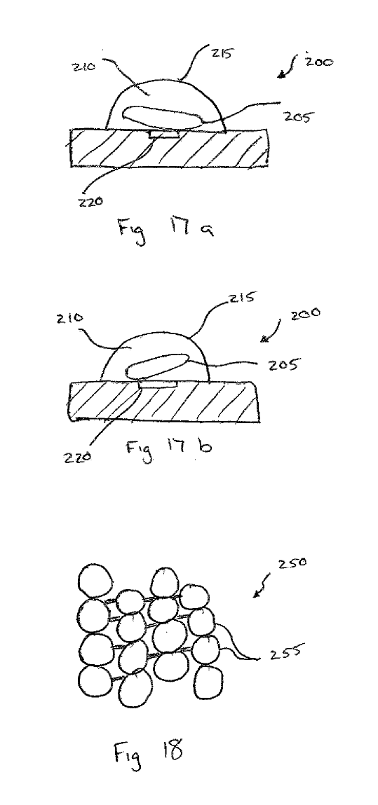

The previous examples have described individual lens compartments, but arrays of such lens compartments may also be constructed according to the disclosed technology. A plurality of lens compartments may be sized, configured, and arranged as desired depending upon a particular application. FIG. 18 shows but one example of such an array 250 of individual lens compartments 255. In this example, the lens compartments 255 are arranged so as to maximize the number of compartments in a given area. In other examples, the lens compartments may be configured to achieve goals other than maximizing space utilization, such as weight distribution or aesthetics.

While the novel technology has been illustrated and described in detail in the drawings and foregoing description, the same is to be considered as illustrative and not restrictive in character. It is understood that the embodiments have been shown and described in the foregoing specification in satisfaction of the best mode and enablement requirements. It is understood that one of ordinary skill in the art could readily make a nigh-infinite number of insubstantial changes and modifications to the above-described embodiments and that it would be impractical to attempt to describe all such embodiment variations in the present specification. Accordingly, it is understood that all changes and modifications that come within the spirit of the novel technology are desired to be protected.

What is claimed is:

1. A solar cell assembly, comprising:
an electric-optically transducing layer;
at least one electrically conducting layer;
an electrically insulating layer positioned between the electric-optically transducing layer and the electrically conducting layer;
a hydrophobic layer;
a dielectric layer positioned between the electrically conducting layer and the hydrophobic layer;
a liquid microdroplet lens positioned in contact with the hydrophobic layer; and
a lens compartment;
wherein the liquid microdroplet lens is disposed within the lens compartment;
wherein the lens compartment, the at least one electrically conducting layer, the hydrophobic layer and the dielectric layer are substantially optically transparent.

2. The assembly of claim 1 wherein the contact angle between the liquid microdroplet lens and the hydrophobic layer is about 120 degrees.

3. The assembly of claim 1 and further comprising a DC voltage source is connected in electric communication with the at least one electrically conducting layer.

4. The assembly of claim 3 and further comprising:
an ammeter connected in electric communication with the electro-optically transducing layer; and
a microprocessor operationally connected to the ammeter;
wherein the microprocessor receives current signals from the ammeter; and
wherein the microprocessor controls the DC voltage source to maximize the current signals from the ammeter.

5. The assembly of claim 4 wherein varying output from the DC voltage source varies the shape of the liquid microdroplet lens.

6. The assembly of claim 1 wherein the liquid microdroplet lens is between about 40 microliters in volume and about 120 microliters in volume.

7. The assembly of claim 1 wherein the liquid microdroplet lens further comprises two immiscible liquid portions.

8. The assembly of claim 7 wherein the liquid microdroplet lens further comprises a first electrically insulating liquid core portion and a second electrically conducting envelope portion.

9. The assembly of claim 1 wherein the at least one electrically conducting layer defines a first electrode and further comprising a second electrode positioned adjacent the microdroplet lens.

10. The assembly of claim 9, wherein the second electrode is electrically divided into two or more sub-electrodes which may selectively be energized.

11. A solar array, comprising:
a plurality of solar panels, wherein each solar panel further comprises:
an electric-optically transducing layer;
a first electrode;
an electrically insulating layer positioned between the electric-optically transducing layer and first electrode;
a plurality of liquid microdroplet lenses;
a hydrophobic layer positioned between the plurality of liquid microdroplet lenses and the a first electrode;
a second electrode operationally positioned adjacent the plurality of liquid microdroplet lenses; and
a plurality of lens compartment enclosures;
wherein the lens compartment enclosures, the first electrode, the electrically conducting layer, and the hydrophobic layer are substantially optically transparent;
wherein each of the plurality of liquid microdroplet lenses is disposed within one of the plurality of lens compartment enclosures;
a voltage source operationally connected to the first and second electrodes;
an ammeter operationally connected to the plurality of solar panels;
a microprocessor operationally connected to the voltage source and to the ammeter;
wherein the microprocessor receives signals from the ammeter;
wherein the plurality of solar panels generates a current;
wherein the microprocessor controls the voltage source to vary the shape of the liquid microdroplet lenses to maximize current produced by the plurality of solar panels.

12. The array of claim 11 wherein each respective liquid microdroplet lens further comprises a first electrically insulating portion and a second electrically conducting portion; and wherein the first electrically insulating portion and a second electrically conducting portion are immiscible.

13. The array of claim 12 wherein the second electrically conducting portion of each respective droplet is connected in fluidic communication with a reservoir; and wherein circulation of the electrically conducting portion of each respective droplet removes heat from the plurality of solar panels.

14. The array of claim 11 wherein each respective droplet is connected in fluidic communication with a reservoir; and wherein each respective droplet removes heat from the plurality of solar panels.

15. The array of claim 11 wherein the microprocessor is programmed to vary the shape of each respective droplet relative to the position of the Sun.
